(19) United States
(12) Patent Application Publication
(10) Pub. No.: US 2005/0178655 A1
(43) Pub. Date: Aug. 18, 2005

(54) Article coated with zirconium compound film, method for preparing the article and sputtering target for use in coating with the film

(75) Inventors: Toshiaki Anzaki, Osaka (JP); Daisuke Inaoka, Osaka (JP); Yoshifumi Kijima, Osaka (JP)

Correspondence Address: BIRCH STEWART KOLASCH & BIRCH, PO BOX 747, FALLS CHURCH, VA, 22040-0747, US

(73) Assignee: Nippon Sheet Glass Co., Ltd.

(21) Appl. No.: 11/100,462

(22) Filed: Apr. 7, 2005

Related U.S. Application Data
(62) Division of application No. 10/651,040, filed on Aug. 29, 2003.

(30) Foreign Application Priority Data
Aug. 29, 2002 (JP) 2002-250116
Jun. 20, 2003 (JP) 2003-176242

(51) Int. Cl. C23C 14/32

(52) U.S. Cl. 204/192.26; 204/192.16; 204/192.27; 204/192.28

(57) ABSTRACT

A method for forming a zirconium compound film on a substrate by a sputtering process using a zirconium target which contains a metal (such as tin or zinc) of which the sputtering yield in an argon atmosphere is more than twice that of zirconium in place of a conventional metallic zirconium target. An article coated with the zirconium compound film and a sputtering target used for coating the film are provided. It is desirable that the content of the metal be 1-45 at %, but a third metal can be added thereto.

This is a divisional application claiming priority of U.S. patent application Ser. No. 10/651,040 filed on Aug. 29, 2003; which was a Nonprovisional application claiming priority under 35 U.S.C. § 119(a) on Patent Applications No. 2002-250116 and 2003-176242 filed in JAPAN on Aug. 29, 2002 and Jun. 20, 2003, respectively, the entire contents of which are incorporated by reference.

### BACKGROUND OF THE INVENTION

1. Field of the Invention

The present invention relates to formation of a zirconium compound film used in all sorts of members such as a windowpane for building, a glass plate for display, a glass substrate for DNA analysis, a solar cell, a portable information device, hygienic and medical equipment, electronics, an optical component, an inspection chip for a biomedical application, an optical fiber for operation and medical endoscope, material for hydrogen-oxygen-generating equipment, and a titanium compound film material having photocatalytic activity formed on the zirconium compound film or an optical film material for communication.

2. Description of the Prior Art

In the case where a zirconium compound film is prepared in the conventional art, a metallic zirconium target is used as a starting material. By sputtering the target in the presence of oxygen or nitrogen, a zirconium oxide film, a zirconium nitride film or a zirconium oxide-nitride film are formed.

A sputtering yield is often used as an indicator of the efficiency of sputtering. The sputtering yield is described as follows in a non-patent document 1.

Namely, the sputtering yield is the percentage of the number of atoms sputtered per incident ion. A material with large value shows a large deposition (film-forming) rate by sputtering. The sputtering yield varies with a target material with reference to the same incident ion, wherein the less the surface bonding energy of the material, the larger the sputtering yield. Namely, the sputtering yield varies with the material and in general, an easily sputtered material shows a larger sputtering yield. Thus, the sputtering yield can be the indicator of ease of sputtering the material.

However, to use the sputtering yield as the indicator, it is necessary to use the sputtering yield measured by the same equipment and in the same condition. The value measured by the same equipment and in the same condition becomes a meaningful value as the indicator of ease of sputtering, but it is not so meaningful to make a comparison between each sputtering yield measured by different equipment and under different conditions. In other words, the sputtering yield varies with the measuring method and the measuring condition and even the sputtering yield of the same material varies greatly. It is therefore wise to not use the value of the sputtering yield of each material obtained from different experiments as the indicator of ease of sputtering.

[Non-Patent Document]

Non-patent document 1: Pages 68-85 of a first edition of a book entitled “Thin-Film Technology” written by HAYAKAWA Shigeru and WASA Kiyotaka in 1982 (publisher: Kyoritsu Publishing Co., Ltd.)

In the case where a zirconium compound film is formed from a metallic zirconium target by a conventional method, the film-forming (deposition) rate is small (low) because the sputtering yield of zirconium is small and it is hard for the zirconium to be sputtered. There was also a problem that high output could not be input because the target surface reacts to reactive gas to form an insulating film and the surface is electrostatically charged to generate arcing.

### SUMMARY OF THE INVENTION

It is therefore an object of the present invention to solve a low film-forming (deposition) rate and a problem that high output can not be input due to generation of arcing in the case where a zirconium compound film is formed (deposited) by a reactive sputtering process on the surface of a substrate such as a plate-shaped glass.

To solve the above-mentioned problems, according to the present invention, a zirconium compound film was formed on a substrate by a sputtering process by using a sputtering target containing a metal of which the sputtering yield in an argon atmosphere is more than twice that of zirconium (hereinafter referred to as “metal with a large sputtering yield”) in place of a conventional metallic zirconium target. By using the sputtering target containing the metal with a large sputtering yield, it is possible to secure a larger film-forming (deposition) rate than in using the conventional metallic zirconium target.

According to the present invention, the ratio of sputtering yields between the metal with a large sputtering yield and the zirconium means the ratio of the measured value of sputtering yields between the metal and the zirconium measured in the same condition in the presence of argon. The ratio is used as a factor for showing the ratio of ease of sputtering the metal with a large sputtering yield and the zirconium in the same condition. The sputtering yield varies with the energy of an argon ion, but in the present invention, the sputtering yield relative to the argon having an energy range used on the actual sputtering film-forming (deposition) is used. For example, the sputtering yield relative to argon having energy in the range of 200-700 eV is favorably used. In the case of measuring the sputtering yield, it is desirable that other sputtering conditions be the same as the actual film-forming (deposition) condition.

A measuring method for the sputtering yield is not particularly limited. However, a method measured by a group in which Wehner plays a central part [e.g., N. Laegreid and G K. Wehner, J. Appl. Phys., 32, 365 (1961) and D. Rosenberg and G. W. Wehner, J. Appl. Phys., 33, 1842 (1962)] can be used in the same manner.

In the present invention, a film-forming rate (a deposition rate) in an argon atmosphere can also be used in place of the sputtering yield. When the sputtering yield is large, the deposition rate has a tendency to be large. Accordingly, it is also possible to express the present invention using the deposition rate as a parameter. The deposition rate of each metal also uses the value measured in the same condition as in the actual deposition in the same manner as sputtering yield.

In the present invention, the sputtering target containing the metal of which the sputtering yield in an argon atmosphere is more than twice that of zirconium (i.e., the metal with a large sputtering yield) is used. The metal is sputtered prior to the zirconium in the case of sputtering and as a result, the texture of the target surface becomes rough, then the bond density of zirconium decreases and an exposed surface area increases. In this manner, subsequent sputtering of zirconium is accelerated and the deposition rate of the sputtering target becomes large as a whole.

Tin, zinc, nickel, iron and indium are preferably used as the metal with a large sputtering yield according to the present invention. However, when at least a kind of metal selected from a group consisting of tin, zinc and indium is used, the metal oxidized in a sputtering process exhibits electrical conductivity, and the electrostatic charge on the target surface and arcing due to the charge are controlled. In this manner, it is possible to apply high electric power to the target and to realize a large deposition rate. Thus, tin, zinc and indium are optimally used as the metal with a large sputtering yield. It is to be understood that the metal with large sputtering yield according to the present invention can exist in a metal state or in an oxidation state in the sputtering target.

In the conventional zirconium metallic target, there is a problem that arcing is easily caused on the target surface during deposition under the influence of electric non-conductance of an oxide film formed on the target surface in sputtering and as a result, high power cannot be input. According to the present invention, this problem can be solved.

Although the metal with a large sputtering yield included in the target is contained in the zirconium compound film formed in the sputtering process, the metal, if the amount is small, does not form a large disincentive relative to the film function. Accordingly, it is possible to form a zirconium compound film containing a small amount of the metal with a large sputtering yield on the substrate. Further, in the case where the metal with a large sputtering yield does not so much affect the characteristic (such as an optical function) which the zirconium compound film formed exhibits, it is possible to make use of desired characteristics even though the metal is included to a certain degree.

To separate the metal with large sputtering yield included in the zirconium compound film from the zirconium compound, it is effective to heat-treat the metal during and/or after deposition in some cases. By way of such heat-treatment (e.g., in vacuum, temperature 300° C., one hour), it is possible to somewhat separate a composition phase of the zirconium compound such as a zirconium oxide from a phase of the metallic compound such as the metal oxide in some cases.

Referring to a use whereby the metal with large sputtering yield in the film is caused to effectively function (e.g., the application whereby the metal is used as an additive for accelerating crystallization to improve crystallinity of the zirconium compound), it is not necessary to make such separation actively. By adjusting the degree of separation, the amount of the metal with a large sputtering yield can also be arbitrarily adjusted.

However, since the film is easily crystallized even at a low temperature, heating is normally unnecessary for the purpose of crystallization.

In a use whereby the metal in the film is caused to effectively function, it is desirable that the content of the metal in the zirconium compound film be 1-45 at % (metal conversion). When the metal content is less than 1 at %, it is not suitable because a function for increasing the deposition rate by the metal is not recognized so much. On the other hand, the metal content, if more than 45 at %, is not suitable because crystallinity of the zirconium compound decreases and the metal can not be easily used for a use (e.g., an undercoat film for a photocatalytic film) whereby crystallinity is effectively used.

Further, the desirable metal content is 1-30 at %. When the metal content is more than 30 at %, it is not suitable because durability tends to decrease. For example, when zinc content is more than 30 at %, it reacts to water under irradiation of light, wherein a zinc oxide itself is decomposed thereby to lower the durability of a film.

Referring further to the composition of the sputtering target, an equivalent range is desirable for the above reason.

Used as the sputtering target are a solid solution of zirconium and the metal, a mixture of zirconium and the metal, a compound of zirconium and the metal, and a combination of the above, etc. The target used in the present invention is not necessarily produced by any specific production method, but can be produced by a known method. For example, a method for sintering raw powder of zirconium and the metal in a non-oxidizing atmosphere (a powder sintering method and a sintering fusion method), a method whereby raw material is atomized in plasma or arc to be deposited on a substrate (a thermal spraying or sputtering method), etc. are proposed. It is however necessary to take measures and pay attention to ignition and the like because metallic zirconium powder is easily and suddenly oxidized in the presence of oxygen.

A carbon-containing zirconium can be used as a base material for the sputtering target. The carbon in the target reacts to a reactive gas atmosphere such as oxygen, hydrogen and water in sputtering and is emitted as CO₂ gas, CO gas or HC gas, wherein carbon on the target surface is first eliminated (etching). As a result, the texture of the target surface becomes rough to increase an exposed surface area of zirconium. In this manner, sputtering of the zirconium is accelerated to further increase the deposition rate.

Further, since carbon is oxidized prior to zirconium in the sputtering process, it is possible to prevent formation of an insulating film due to oxidization of metallic zirconium on the target surface, wherein an electrostatic charge on the target surface and arcing arising from the charge are controlled. In this manner, it is possible to apply high power to the target thereby realizing a larger deposition rate.

The carbon included in the target becomes CO₂ gas, CO gas or HC gas in the presence of reactive gas in the sputtering process, and then it is emitted from a chamber by a vacuum pump. In this manner, it is possible to form a zirconium compound film containing only a small amount of carbon on the substrate.

By performing sputtering in the presence of a reactive gas such as oxygen, nitrogen, hydrogen and water using a sputtering target containing the metal with large sputtering yield according to the present invention, it is possible to obtain a zirconium compound film such as zirconium oxide, zirconium nitride and zirconium oxide-nitride at a high deposition rate. The deposition rate becomes 2-10 times higher than in the conventional zirconium metallic target and thus productivity remarkably improves compared to the conventional method.

Further, if at least a kind of metal selected from a group consisting of calcium, yttrium, magnesium and neodymium is caused to be contained at 0.1-45 at %, preferably 0.1-20 at % in the sputtering target according to the present invention, it is possible to stabilize a column structure and growth of the crystal of the zirconium compound film. Such a zirconium compound film into which a crystallization accelerating additive is added to promote and stabilize the columnar structure and crystal growth in a low temperature process is easily crystallized even in the low temperature and shows high crystallinity. If this zirconium compound film is used as an undercoat film for the photocatalytic or optical function material such as a titanium compound film, it can exhibit excellent photocatalytic performance and optical function properties.

The substrate for forming the zirconium compound film can be any material which does not suffer damage in the case of sputtering deposition, such as a plate-shaped glass, a plate-shaped plastic, a glass block, a plate-shaped ceramic, a cloth-shaped glass fiber. However, a plate-shaped glass such as a soda-lime silica glass, a soda-lime silica glass on which a metallic oxide layer is formed, and a silica glass is particularly suitable from the viewpoint of durability and maintenance of functionality. If the above-mentioned production method is combined with a mass separation method or an evaporation method in gas, fine zirconium compound articles including the zirconium oxide can also be formed at a high speed.

If a titanium compound film such as a titanium oxide film, a titanium nitride film and a titanium oxide-nitride film is additionally formed on the zirconium compound film by the sputtering process, a photocatalytic function etc. of the titanium compound film can be improved under the influence of the zirconium compound film. This results from the crystallinity of the zirconium compound assisting the crystallinity of the titanium compound. Thus, it is highly desirable to be capable of reducing the thickness of the titanium compound film from a film-design point of view.

Further, when the zirconium compound film is formed on a substrate on which a crystalline zirconium oxide film has been formed in advance, the crystallinity of the zirconium compound film can be improved to obtain a still better film under the influence of the crystalline zirconium oxide film. In this manner, if the zirconium compound film of which the crystallinity is better is used as an undercoat film for the titanium compound film such as a titanium oxide, it is possible to obtain the titanium compound film with high photocatalytic activity.

### BRIEF DESCRIPTION OF THE DRAWINGS

The above and other objects, features and advantages of the present invention will become more apparent from the following description when taken in conjunction with the accompanying drawings.

FIG. 1 shows an XRD pattern of ZrO₂ and ZrSnₓO_{y} samples deposited on Zr, Zr—Sn (20 at %) and Zr—Sn (40 at %) targets according to the present invention; and

FIG. 2 shows an XRD pattern of samples on which TiO₂ film was laminated by a Ti target on ZrO₂ and ZrSnₓO_{y} deposited at Zr, Zr—Sn (20 at %) and Zr—Sn (40 at %) targets according to the present invention.

### DETAILED DESCRIPTION OF THE PREFERRED EMBODIMENTS

Preferred embodiments and comparative examples of the present invention will be specifically described hereunder.

### EMBODIMENTS 1-12, COMPARATIVE EXAMPLES 1-3

Various targets, the size of 15 inches×5 inches, shown in Table 1 are mounted on magnetron sputtering equipment of which the distance between a substrate position and a target is 65 mm. A zirconium compound film is deposited at target input power of 3 kW while conveying various substrates (100-mm-square, 3-mm-thickness) at a constant speed (1 m/min) under the conditions shown in Table 1.

The zirconium compound film of a given thickness was deposited by repeating a process for passing the substrate given number of times (i.e., given pass number of times). In the case where a titanium compound film such as a titanium oxide and a titanium oxide-nitride is further formed on the zirconium compound film, metallic titanium is used as a target, wherein the titanium compound film is formed in the same manner as in the deposition of a zirconium compound film under gas pressure of 3 mTorr (0.4 Pa) using the above equipment. In the case of deposition of a titanium oxide film, the gas composition used here was set at argon:oxygen=1:1. In the case of deposition of a titanium oxide-nitride film, the gas composition was set at argon:oxygen:nitrogen=10:9:1.

The thickness of the zirconium compound film and titanium compound film was obtained by measuring a step between a non-deposited section and a deposited section using a stylus-type thickness-meter (DecktackIID made by Sloan Company).

The deposition rate (dynamic rate) was calculated by the thickness of a film deposited on a substrate when passing once below the target at a conveyance speed of 1 m/min in the deposition output of 1 kW. The following formula was used for calculation.
Deposition rate=film thickness×conveyance speed÷(deposition pass number of times×target input power)

Crystallinity of the thin film was evaluated by using X-ray diffractometry for thin film for the purpose of examining the crystallinity of the zirconium compound film and the titanium compound film.

The measured data of analytic results of these film thickness, deposition rate and X-ray diffraction are shown in Table 1.

As comparative examples, deposition of a zirconium compound film and a titanium compound film was made under the conditions shown in Table 2 by using the same sputtering equipment as above except that a target of a metallic zirconium system is used. The same measurements as for the embodiments were made and the data obtained is shown in Table 2. The thickness of the zirconium compound film, the deposition rate, crystallinity of the thin film and the sputtering yield were measured and observed by the same method as for the embodiments above. In the embodiments 7 and 8 of Table 1 and the embodiments of Table 2, that the deposition rate differs even in the substantially same condition is because the deposition rate greatly varies with the equipment used. Namely, when the deposition equipment is changed and the density of a magnetic field is low, ion density in plasma decreases and formation of an oxide film on the target surface advances. As a result, the rate of the zirconium target decreases. However, no matter what equipment is used, the deposition rate improves more when the target in which the other metal is mixed in the titanium at a predetermined percentage is used than when the target of titanium alone is used.

TABLE 1

| | Embodiment 1 | Embodiment 2 | Embodiment 3 | Embodiment 4 | Embodiment 5 | Embodiment 6 |
|---|---|---|---|---|---|---|
| Film composition | TiO₂ | TiO₂ | TiO₂ | — | TiO₂ | TiO₂ |
| | ZrZnOxide | ZrZnOxide | ZrZnOxide | ZrZnOxide | ZrSnON | ZrSnYOxide |
| Substrate | Soda-lime glass | Glass with | Soda-lime glass | Soda-lime glass | Soda-lime glass | Soda-lime glass |
| | | ZrO₂ film | | | | |
| Target (Figure shows | 90 Zr - 10 Zn | 80 Zr - 20 Zn | 80 Zr - 20 Zn | 90 Zr - 10 Zn | 80 Zr - 20 Sn | 60 Zr - 10 |
| a molar ratio) | | | | | | Sn - 30Y |
| Sputtering gas | Ar:O₂ = 50:50 | Ar:O₂ = 50:50 | Ar:O₂ = 50:50 | Ar:O₂ = 50:50 | Ar:O₂:N₂ = 50:25:25 | Ar:O₂ = 50:50 |
| composition | | | | | | |
| Sputtering gas | 0.4 | 0.4 | 0.4 | 0.4 | 0.4 | 0.4 |
| pressure (Pa) | | | | | | |
| Treatment after | — | — | — | After-baking | — | — |
| deposition | | | | | | |
| Ti compound film | 20 | 30 | 30 | 10 | 100 | 100 |
| thickness (nm) | | | | | | |
| Zr compound film | 20 | 10 | 15 | 10 | 500 | 300 |
| thickness (nm) | | | | | | |
| Zr deposition rate | 1.7 | 2.1 | 2.1 | 1.7 | 2.3 | 1.8 |
| [nm · m/(min · kW)] | | | | | | |
| X-ray diffraction analysis | Crystalloid | Crystalloid | Crystalloid | — | Crystalloid | Crystalloid |
| (Ti compound) | | | | | | |
| X-ray diffraction analysis | Crystalloid | Crystalloid | Crystalloid | Crystalloid | Crystalloid | Crystalloid |
| (Zr compound) | | | | | | |
| | Embodiment 7 | Embodiment 8 | Embodiment 9 | Embodiment 10 | Embodiment 11 | Embodiment 12 |
| Film composition | TiO₂ | — | TiO₂ | TiOxNy | TiO₂ | TiO₂ |
| | ZrSnOxide | ZrSnOxide | ZrZnOxide:Mg | ZrZnOxide | ZrSnOxide | ZrSnOxide |
| Substrate | Soda-lime glass | Soda-lime glass | Soda-lime glass | Soda-lime glass | Soda-lime glass | Soda-lime glass |
| Target (Figure shows | 60 Zr - 40 Sn | 80 Zr - 20 Sn | 90 Zr - 9.8 Zn : | 80 ZrC - 20 Zn | 80 ZrC - 20 Sn | 80 ZrC - 20 |
| a molar ratio) | | | Mg 0.2% | | | Sn - Oxide |
| Sputtering gas | Ar:O₂ ± 50:50 | Ar:O₂ ± 50:50 | Ar:O₂ ± 50:50 | Ar:O₂ ± 50:50 | Ar:O₂ ± 50:50 | Ar:O₂ ± 50:50 |
| composition | | | | | | |
| Sputtering gas | 0.4 | 0.4 | 0.4 | 0.4 | 0.4 | 0.4 |
| composition (Pa) | | | | | | |
| Treatment after | — | — | — | — | — | — |
| deposition | | | | | | |
| Ti compound film | 20 | 100 | 50 | 50 | 50 | 50 |
| thickness (nm) | | | | | | |
| Zr compound film | 20 | 100 | 50 | 50 | 50 | 50 |
| thickness (nm) | | | | | | |
| Zr deposition rate | 3.4 | 2.3 | 1.7 | 2.2 | 2.7 | 2.4 |
| [nm · m/(min · kW)] | | | | | | |
| X-ray diffraction analysis | Crystalloid | — | Crystalloid | Crystalloid | Crystalloid | Crystalloid |
| (Ti compound) | | | | | | |
| X-ray diffraction analysis | Crystalloid | Crystalloid | Crystalloid | Crystalloid | Crystalloid | Crystalloid |
| (Zr compound) | | | | | | |

TABLE 2

| | Comparative | Comparative | Comparative |
|---|---|---|---|
| | example 1 | example 2 | example 3 |
| Film composition | TiO₂ | — | TiO₂ |
| | ZrO₂ | ZrO₂ | 70ZrO₂—15Nb₂O₅ |
| Substrate | Soda-lime | Soda-lime | Soda-lime glass |
| | glass | glass | |
| Target (Figure shows a | Zr (four | Zr (four | 70Zr—30Nb |
| molar ratio) | nines) | nines) | |
| Sputtering gas | Ar:O₂ = | Ar:O₂ = | Ar:O₂ = 50:50 |
| composition | 50:50 | 50:50 | |
| Sputtering gas | 0.4 | 0.4 | 0.4 |
| pressure (Pa) | | | |
| Treatment after | — | — | — |
| deposition | | | |
| Ti compound film | 100 | — | 100 |
| thickness (nm) | | | |
| Zr compound film | 50 | 100 | 100 |
| thickness (nm) | | | |
| Zr deposition rate | 1.1 | 1.1 | 1.1 |
| [nm · m/(min · kW)] | | | |
| X-ray diffraction | Crystalloid | — | Crystalloid |
| analysis | | | |
| (Ti compound) | | | |
| X-ray diffraction | Crystalloid | Crystalloid | Crystalloid |
| analysis | | | |
| (Zr compound) | | | |

The sputtering yields of various metals were measured using hot-cathode discharge according to the procedures described in a thesis [(G. K. Wehner, Phys. Rev., 102, p690 (1956) or G. K. Wehner, Phys. Rev., 108, p35 (1957)] written by Wehner et al. The target of the metal (atomic weight M) to be measured is prepared, wherein the mass thereof is measured in advance. The target is first installed in position and then, an exhaust velocity is adjusted to have the gas pressure of 3 mTorr (0.4 Pa) while introducing argon gas. After this, a potential difference of about 400V is applied between an anode and a cathode and electricity is discharged for one hour (3,600 seconds) while recording ion current I (unit A). After discharge, mass defect ΔW (unit g) of the target is measured by an electronic scale. The sputtering yield S was found by the following formula.
S=(ΔW×N_{A}×e)/(M×I×3600)
where N_{A} is Avogadro's number (=6.022×10²³/mol) and e is an elementary electric charge (=1.602×10⁻¹⁹C).

The sputtering yields of zirconium, zinc, tin and niobium were measured according to the method above and as a result, each yield was 0.6, 2.6, 3.1 and 0.6. Namely, the sputtering yield of zinc is about 4.3 times higher than zirconium, the sputtering yield of tin is about 5.2 times higher than zirconium, and the sputtering yield of niobium is about equal to that of zirconium, respectively.

The deposition rates of various metals were measured according to the following procedures after pre-sputtering was performed for 15 minutes at an output of 1 kW in the presence of argon and the oxide film of the target was removed. A model “SCH-3030” made by ULVAC Co. Ltd. was used as deposition equipment. A metallic target having a size of 20×5 inches was used, the deposition output was set at 1 kW and then, two pass depositions were carried out at a conveyance speed of 1 m/min in the presence of argon at—3 mTorr (0.4 Pa). A step between a deposited section and a non-deposited section is measured using the stylus-type thickness-meter and the deposition rate was calculated using the formula described above.

The deposition rate of zirconium, zinc, tin, and niobium was found and as a result, the rates were measured at 14 nm.m/min, 41 nm.m/min, 66 nm.m/min and 15 nm.m/min, respectively. Namely, the deposition rate of zinc is about 2.9 times higher than zirconium, the deposition rate of tin is about 4.7 times higher than zirconium, and the deposition rate of niobium is about 1.1 times that of zirconium.

The deposition rates of zirconium compound film of the embodiments 1 through 12 in which the deposition was performed using the zirconium target which contains zinc and tin of which both the sputtering yield and the deposition rate are more than twice those of zirconium are larger (the largest deposition rate is about three times larger) than the deposition rates of zirconium compound film in the comparative examples 1 and 2 in which the deposition was performed using a metallic zirconium target and in the comparative example 3 in which the deposition was performed using zirconium target which contains niobium of which the sputtering yield is small. In this manner, improvement of the deposition efficiency was recognized. It is also obvious that a high deposition rate is maintained even though the sputtering target to which a third metal described in the embodiments 6 and 9 is added, or it is doped.

Table 3 below shows the percentage of Sn in the target, the ratio of deposition rate, UV response hydrophilicity of deposited laminating film and hydrophilic sustainment in a dark place. It is clear from this table that when the percentage of Sn increases, the ratio of deposition rate increases, but the UV response hydrophilicity is best in the vicinity of an amount of Sn addition of 20 at %, while the hydrophilic sustainment in a dark place is equivalent to ZrO₂ until amount of Sn addition reaches 20 at %. Referring to the laminating film according to Table 3, the deposition is performed using the sputtering equipment described in the embodiments 1 through 12, wherein a structure of glass substrate/SiO₂ (10 mm thick)/ZrO₂ or ZrSnₓO_{y} (25 nm thick)/TiO₂ (50 nm thick) is shown. As for a ZrSnₓO_{y} film, the sputtering deposition was performed using the target described in table 3 in the presence of argon-oxygen (50:50) of a pressure of 0.4 Pa. As for the UV response hydrophilicity and the hydrophilic sustainment in a dark place, evaluation is started after UV illumination of 1 mW/cm² and acetone cleaning for 10 min.

TABLE 3

| | Ratio of | | | | | Hydrophilic sustainment | | |
|---|---|---|---|---|---|---|---|---|
| | deposition rate | | UV response hydrophilicity | | | in a dark place | | |
| | (vs. Zr | | Before | UV irradiation | | After | | |
| Target | target ratio) | | irradiation | for 60 min | | initialization | 7 days later | |
| Ref.) Zr | 1.0 times | | 51° | 13° | | 0° | 16° | |
| 1) Zr-Sn (2 at %) | 1.1 times | Δ | 51° | 11° | ◯ | 0° | 16° | ◯ |
| 2) Zr-Sn (20 at %) | 1.3 times | ⊚ | 52° | 6° | ◯ | 0° | 15° | ◯ |
| 3) Zr-Sn (40 at %) | 1.5 times | ⊚ | 50° | 26° | Δ | 0° | 27° | Δ |

Compared with Zr target deposition: ⊚: Pretty good ◯: Good Δ: Bad

As shown in Table. 3, the UV response hydrophilicity of ZrSnₓO_{y} (Sn: 2 at %; 20 at %) undercoat film deposition sample is better than the ZrO₂ undercoat film deposition sample.

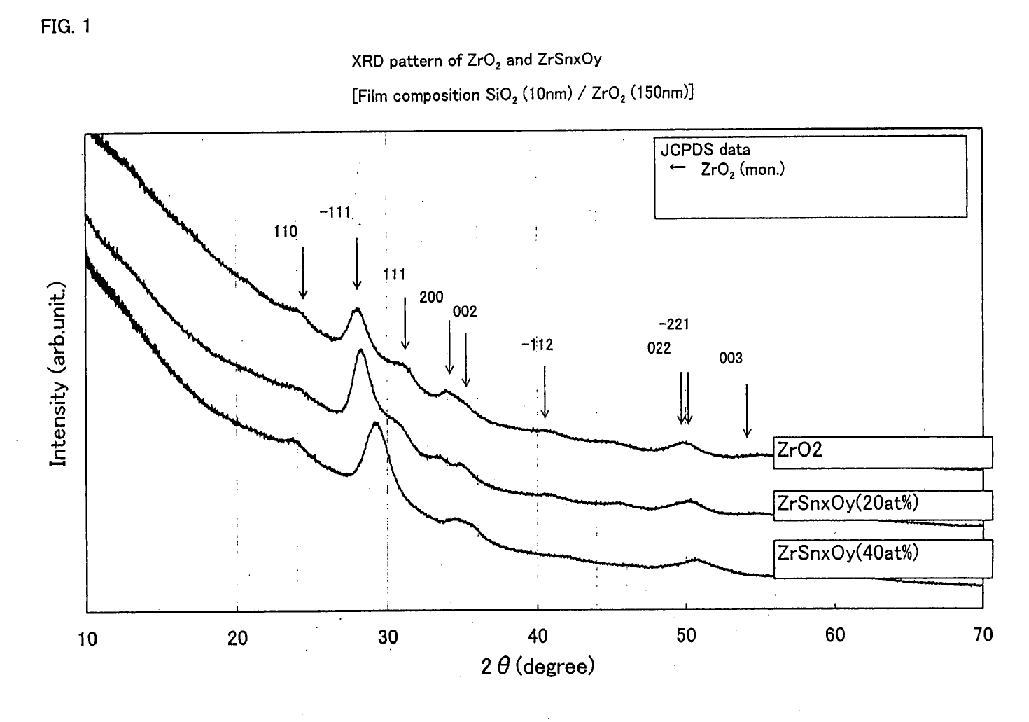

FIG. 1 shows an XRD pattern of ZrO₂ and ZrSnₓO_{y} samples deposited at Zr, Zr—Sn (20 at %) and Zr—Sn (40 at %) targets. Peaks of ZrO₂ mon. shifts by the addition of Sn. This is considered as reduction of lattice spacing by the addition of Sn. (Ion radius:Zr:1.60 Å, Sn:1.55 Å).

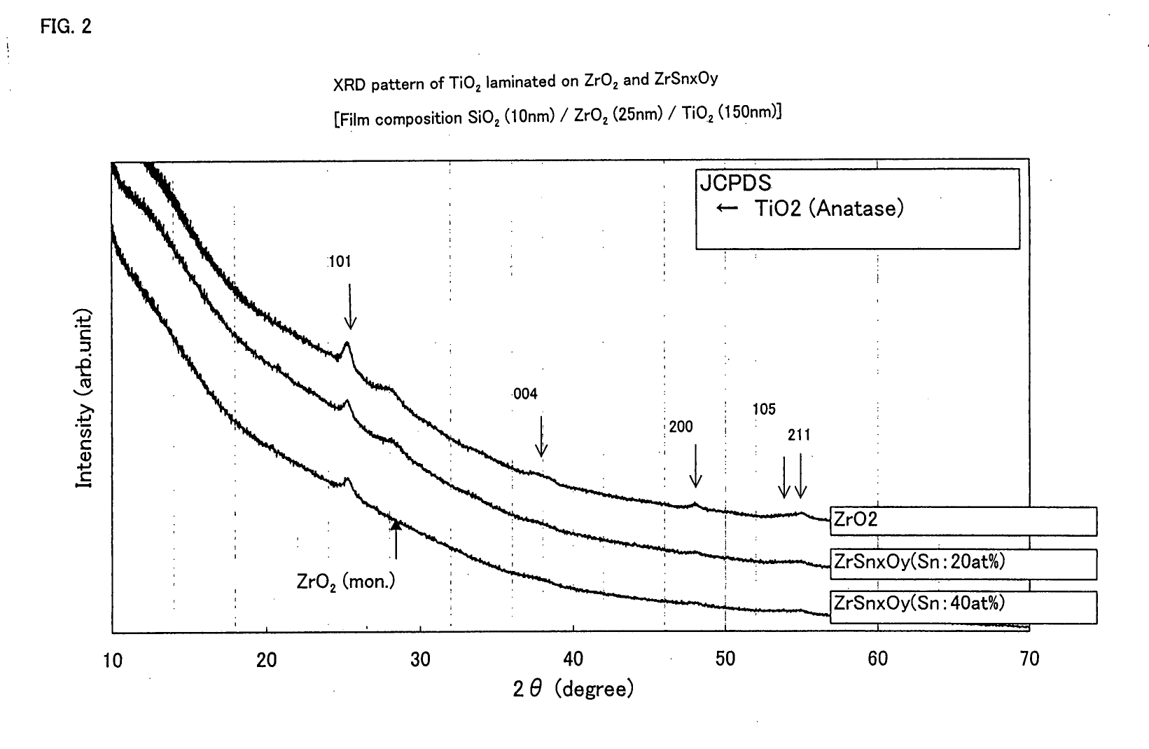

FIG. 2 shows an XRD pattern of samples which laminates TiO₂ at a Ti target on ZrO₂ and ZrSnₓO_{y} deposited at Zr, Zr—Sn (20 at %) and Zr—Sn (40 at %) targets. It is possible to maintain the crystallinity of laminated film TiO₂ even though 40 at % of Sn is added to a seed layer (ZrO₂, ZrSnₓO_{y}).

In the embodiments, a plate-shaped glass is shown as a substrate, but the present invention can also be applied to a plate-shape plastic, a glass block, a plate-shaped ceramic, a cloth-shaped glass fiber, etc.

As described above, according to the present invention, it is possible to increase the deposition rate and reduce the production costs by depositing a zirconium compound by use of a zirconium target which contains tin or zinc in a reactive sputtering process. It is also possible to obtain a zirconium compound film with stable crystallinity by using a zirconium target which contains yttrium, magnesium, etc.

1. A method for producing an article coated with a zirconium compound film comprising the following steps:
using a zirconium target containing a metal of which the sputtering yield in an argon atmosphere is more than twice that of zirconium; and
forming a zirconium compound film that is deposited by a reactive sputtering process on a substrate.

2. The method for producing an article coated with a zirconium compound film according to claim 1, wherein 1-45 at % of the metal is included in the zirconium target containing the metal.

3. The method for producing an article coated with a zirconium compound film according to claim 1, wherein 1-30 at % of the metal is included in the zirconium target containing the metal.

4. The method for producing an article coated with a zirconium compound film according to any one of claims 1 through 3, wherein a main material of the zirconium target containing the metal is at least one of a metallic zirconium and a carbon-containing zirconium.

5. The method for producing an article coated with a zirconium compound film according to any one of claims 1 through 3, wherein the metal is at least a kind of metal selected from a group consisting of tin, zinc and indium.

6. The method for producing an article coated with a zirconium compound film according to any one of claims 1 through 3, wherein a third metal other than the zirconium and the metal is included in the zirconium target containing the metal.

7. The method for producing an article coated with a zirconium compound film according to claim 6, wherein the third metal other than the zirconium and the metal is at least a kind of metal selected from a group consisting of calcium, yttrium, magnesium and neodymium.

8. The method for producing an article coated with a zirconium compound film according to claim 6, wherein the content of the third metal in the zirconium target containing the metal is 0.1-45 at %.

9. The method for producing an article coated with a zirconium compound film according to any one of claims 1 through 3, wherein the zirconium compound is a zirconium oxide.

10. The method for producing an article coated with a zirconium compound film according to any one of claims 1 through 3, wherein the zirconium compound is a zirconium nitride or a zirconium oxide-nitride.

11. The method for producing an article coated with a zirconium compound film according to any one of claims 1 through 3, wherein a substrate coated with the film is a plate-shaped glass.

12. The method for producing an article coated with a zirconium compound film, wherein a zirconium compound film is formed on a substrate coated with a crystallized zirconium oxide film by the method according to any one of claims 1 through 3.

13. The method for producing an article coated with a zirconium compound film having a photocatalytic function or an optical function, wherein a titanium compound film is formed by a sputtering process on the zirconium compound film formed by the method according to any one of claims 1 through 3.

14. The method for producing an article coated with a zirconium compound film having the photocatalytic function or the optical function according to claim 13, wherein the titanium compound film is a titanium oxide film, a titanium nitride film or a titanium oxide-nitride film.

15. The method for producing an article coated with a zirconium compound film according to claim 7, wherein the content of the third metal in the zirconium target containing the metal is 0.1-45 at %.
